(19) United States
(12) Patent Application Publication
(10) Pub. No.: US 2004/0046622 A1
(43) Pub. Date: Mar. 11, 2004

(54) Acoustic resonator

(76) Inventors: Robert Aigner, Unterhaching (DE); Lueder Elbrecht, Munich (DE); Stephan Marksteiner, Putzbrunn (DE); Winfried Nessler, Munich (DE); Hans-Jorg Timme, Ottobrunn (DE)

Correspondence Address: SCHIFF HARDIN, LLP, PATENT DEPARTMENT, 6600 SEARS TOWER, CHICAGO, IL, 60606-6473, US

(21) Appl. No.: 10/380,214

(22) PCT Filed: Sep. 10, 2001
(86) PCT No.: PCT/EP01/10435

(30) Foreign Application Priority Data
Sep. 12, 2000 (DE) 10045090.3

(51) Int. Cl. H03H 9/15

(52) U.S. Cl. 333/187

(57) ABSTRACT

The resonator comprises a first electrode (E1), a second electrode (E2) and a piezoelectric layer (P) arranged between the above. A first acoustic compression layer (V1) is arranged between the piezoelectric layer (E1) and the first electrode (E1) with a higher acoustic impedance than the first electrode (E1).

The invention relates to an acoustic resonator, i.e. a component which converts acoustic waves and changes in electrical voltage into one another.

Such a resonator usually has a series of layers comprising two electrodes and a piezoelectric layer arranged in between. A Bulk Acoustic Wave Resonator comprises, for example, such a series of layers arranged on a membrane or an acoustic mirror (see U.S. Pat. No. 5,873,154 for example). In the range of what is known as series and parallel resonance, standing vertical waves are formed, with approximately one half-wave extending along the entire thickness of the series of layers.

The piezoelectric layer generally consists of a material which, in process-engineering terms, is difficult to deposit, such as AlN for example. To reduce depositing times, resonators with a piezoelectric layer that is as thin as possible are desired.

A thin piezoelectric layer is also to be preferred for the reason that the surface area requirement of the resonator decreases as the piezoelectric layer becomes thinner, with the impedance level remaining the same, with the result that a resonator with a thin piezoelectric layer has a small space requirement. Resonators should have a certain impedance level, in order to ensure a low insertion loss in the pass band of the filter characteristic.

Since the resonant frequency of a resonator is determined by the thickness of all the layers involved of the series of layers, i.e. not only by the thickness of the active piezoelectric layer but also by the thickness of the electrodes, it is possible to reduce the thickness of the piezoelectric layer for a given resonant frequency by increasing the thicknesses of the electrodes. How much a change in layer thickness has an effect on the resonant frequency depends on the acoustic parameters of the electrode. Heavy and hard materials bring about a more pronounced drop in frequency for an increase in layer thickness than lighter and softer materials.

It is customary to produce the electrodes from aluminum, since aluminum is CMOS-compatible, and consequently the resonator can be easily produced. Furthermore, aluminum has a high electrical conductivity. However, the acoustic properties of aluminum are less advantageous.

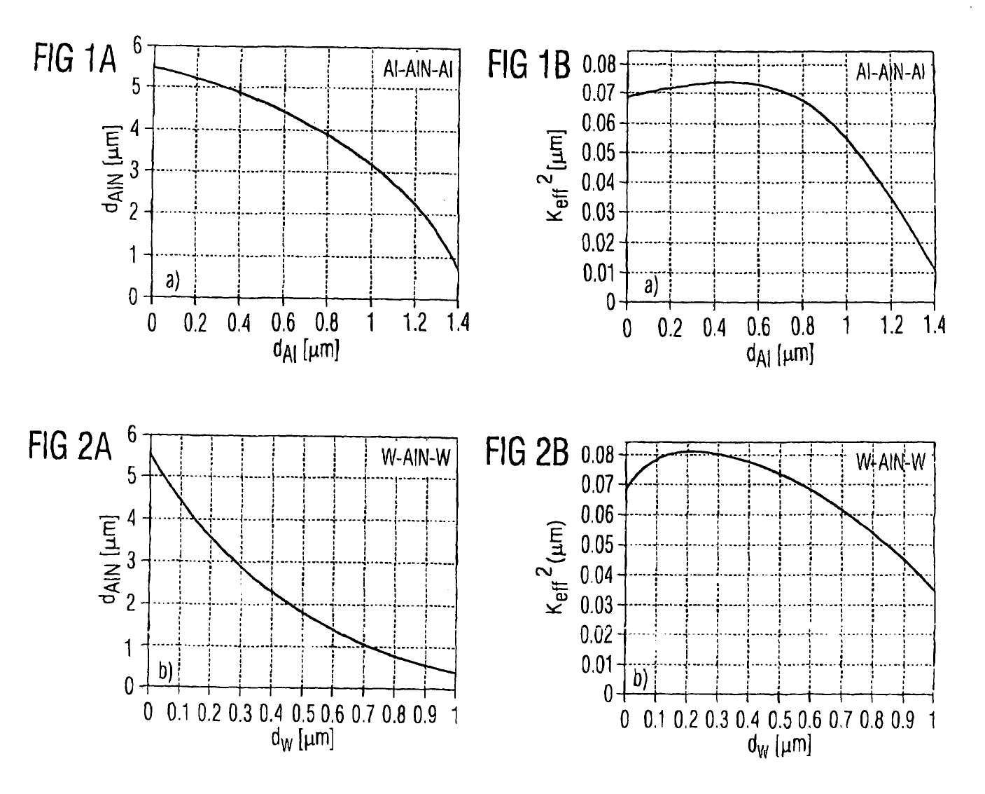

These properties were investigated by the inventors prior to the invention. Some of the results obtained are explained in more detail below: at a resonant frequency of, for example, 900 MHz, the thickness of the piezoelectric layer without electrodes should be approximately 5.5 μm. By providing electrodes, this layer thickness can be reduced with the resonant frequency remaining the same. FIG. 1a shows the dependence of the thickness of the piezoelectric layer on the thickness of the aluminum electrodes for the aforementioned resonant frequency. To achieve a reduction in the thickness of the piezoelectric layer from 5.5 μm to 3 μm, aluminum electrodes about 1.05 μm thick are required. It has been found that, with electrodes of such a thickness, the acoustic properties of the resonator are inadequate, since the effective coupling coefficient is very small for large thicknesses of the aluminum electrodes. The squared coupling coefficient is defined as K_{eff}²=pi\hat{ }2*(fp/fs−1)/4, where fs denotes the series resonant frequency and fp denotes the parallel resonant frequency. FIG. 1b shows the dependence of the squared coupling coefficient on the thickness of the aluminum electrodes, the piezoelectric layer consisting of AlN. Consequently, if it is desired to reduce the thickness of the piezoelectric layer to 3 μm with a resonant frequency of 900 MHz, a considerable drop in the square of the coupling coefficient to below 0.05 must be accepted, which is not acceptable for applications in the GSM band, for example.

It has already been proposed to use tungsten as the material for the electrodes (see U.S. Pat. No. 5,587,620, for example). Investigations prior to the invention have revealed the following: FIG. 2a shows the dependence of the thickness of the piezoelectric layer on the thickness of tungsten electrodes for a resonant frequency of 900 MHz. In comparison with FIG. 1a, it is found that a compensation of the thickness reduction of the piezoelectric layer from 5.5 μm to 3 μm can be achieved with much thinner electrodes, that is about 300 nm thick, if tungsten is used as the electrode material instead of aluminum. The reason for this is the higher acoustic impedance of tungsten. FIG. 2b shows the dependence of the squared coupling coefficient on the thickness of the tungsten electrodes, with the piezoelectric layer consisting of AlN. With electrodes 300 nm thick, the coupling coefficient is very high, with the result that the resonator has very good acoustic properties.

By contrast with the aluminum electrodes, these tungsten electrodes have the disadvantage, however, that the associated resonator has inferior electrical properties, with the result that the insertion loss is too high. The reason for this is that tungsten electrodes 300 nm thick have an electrical resistance that is too high.

To protect the piezoelectric layer during the production of an acoustic resonator, it is proposed in U.S. Pat. No. 5,760,663 to provide a buffer layer of silicon nitride between the piezoelectric layer and the electrodes.

The invention is based on the object of providing an acoustic resonator which has in comparison with the prior art a piezoelectric layer of small thickness and at the same time good acoustic and electrical properties.

The object is achieved by an acoustic resonator with a first electrode, a second electrode and a piezoelectric layer arranged in between, with a first acoustic compression layer, which has a higher acoustic impedance than the first electrode, being arranged between the first electrode and the piezoelectric layer.

The resonator consequently has a series of layers which comprises at least the first electrode, the first compression layer, the piezoelectric layer and the second electrode. At resonance, a half-wave runs along the entire thickness of the series of layers.

The invention is based on the results of the investigations described above and on the perception that the effect of the change in layer thickness of one layer of the series of layers on the resonant frequency depends not only on the acoustic parameters of the layer concerned but also on the position of the layer concerned in relation to the piezoelectric layer. Layers which lie near the piezoelectric layer have a stronger effect than layers which lie further away.

The provision of the first compression layer has the effect of reducing the thickness of the piezoelectric layer with the resonant frequency remaining the same. The material of the first compression layer may be chosen such that even a thin first compression layer is adequate to reduce the thickness of the piezoelectric layer considerably. As a result, the coupling coefficient remains high, with the result that the resonator has good acoustic properties.

Since the first electrode is further away from the piezoelectric layer than the first compression layer, it contributes only little to the acoustic properties of the resonator. The material of the first electrode can be chosen without regard to acoustic properties such that the electrical resistance is small, with the result that the resonator has good electrical properties. For example, electrodes made of Al with thicknesses of 300-600 nm, which lead to a low electrical resistance, bring about only a slight deterioration in the coupling coefficient achieved by providing the first compression layer, and bring the resonant frequency down insignificantly, which can be compensated in turn by an additional (desired) small reduction in the thickness of the piezoelectric layer.

The invention makes it possible to optimize the acoustic and electrical properties of the resonator independently of each other for any desired thickness of the piezoelectric layer. Furthermore, it is possible even with a small thickness of the piezoelectric layer to achieve good acoustic and electrical properties of the resonator.

Particularly good acoustic properties are achieved if the ratio of the acoustic impedance of the first compression layer to the acoustic impedance of the piezoelectric layer is as great as possible. Preferably, the ratio of the acoustic impedance of the first electrode to the acoustic impedance of the first compression layer is as small as possible.

Suitable in particular as materials of the first compression layer with high acoustic impedance are W, Mo, Pt, Ta, TiW, TiN, Ir, WSi, Au, Al₂O₃, SiN, Ta₂O₅ and zirconium oxide. The last four materials are dielectrics.

Conductive materials are used with preference for the compression layer, the first 9 materials listed above being particularly preferred. Conductive materials prevent in particular the formation of series capacitances, such as would occur in the case of dielectric materials.

Suitable for example as materials of the piezoelectric layer are AlN, ZnO, PZT, LiNbO₃.

The electrode material may be chosen such that its conductivity is even adequate to produce connecting lines from the electrode material. Consequently, when an electrode is being created, connecting lines can be produced at the same time. The electrode may be part of such a connecting line.

The electrode material may be chosen such that it is suitable for bonding with connecting lines. For example, the first electrode or the second electrode serves as a bonding pad on which a connecting line is soldered.

The electrodes preferably consist substantially of aluminum, titanium, silver or copper. In particular, Al and Cu have a high electrical conductivity and are additionally CMOS-compatible.

To ensure an adequately low electrical resistance of the electrodes, the electrodes are preferably at least 200 nm thick.

Particularly good acoustic and electrical properties of the resonator are achieved if, along with the first compression layer, a second compression layer is also provided, arranged between the second electrode and the piezoelectric layer.

The acoustic resonator may be designed as a Bulk Acoustic Wave Resonator. The series of layers may be arranged on a membrane or an acoustic mirror. In this case, the first electrode or the second electrode may be adjacent to the acoustic mirror or the membrane. Strictly speaking, the membrane or the acoustic mirror also influences the resonant frequency. However, the influence is small. Consideration of the membrane or the mirror when optimizing the acoustic and electrical properties of the resonator is possible, but not necessary.

It is particularly preferred if the material of the compression layer/s is chosen such that the ratio of the acoustic impedance of the compression layer/s to the acoustic impedance of the piezoelectric layer is greater than 2.

Furthermore, it is preferred if the material of the first electrode is chosen such that the ratio of the acoustic impedance of the first electrode to the acoustic impedance of the compression layer/s is less than ⅓.

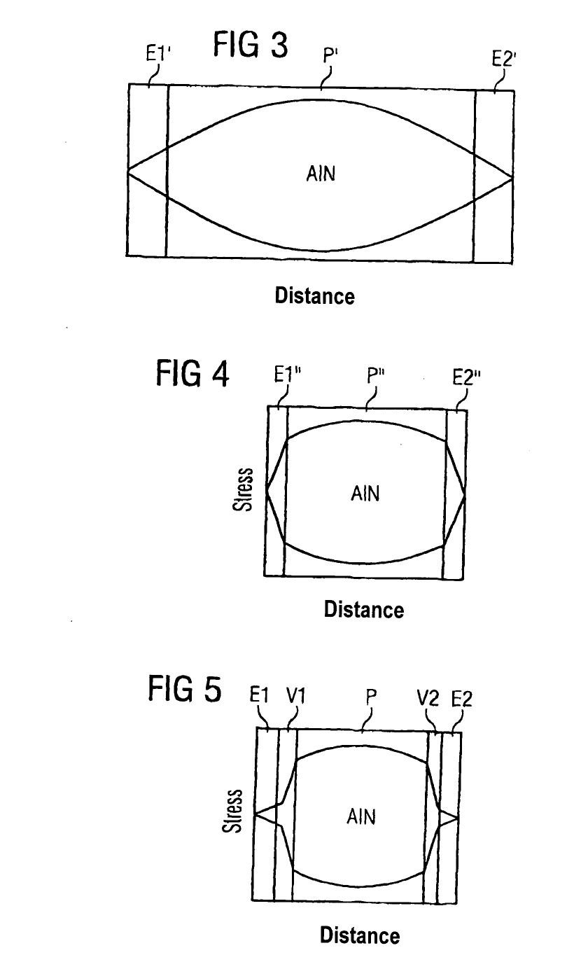

Two comparative examples and one exemplary embodiment of the invention are explained in more detail below on the basis of FIGS. 3 to 6.

FIG. 3 shows a cross section through a first resonator with a first electrode made of aluminum, a piezoelectric layer and a second electrode made of aluminum. Furthermore, the stress field of an acoustic wave at resonance is represented.

FIG. 4 shows a cross section through a second resonator with a first electrode made of tungsten, a piezoelectric layer and a second electrode made of tungsten. Furthermore, the stress field of an acoustic wave at resonance is represented.

FIG. 5 shows a cross section through a third resonator with a first electrode made of aluminum, a first compression layer made of tungsten, a piezoelectric layer, a second compression layer made of tungsten and a second electrode made of aluminum. Furthermore, the stress field of an acoustic wave at resonance is represented.

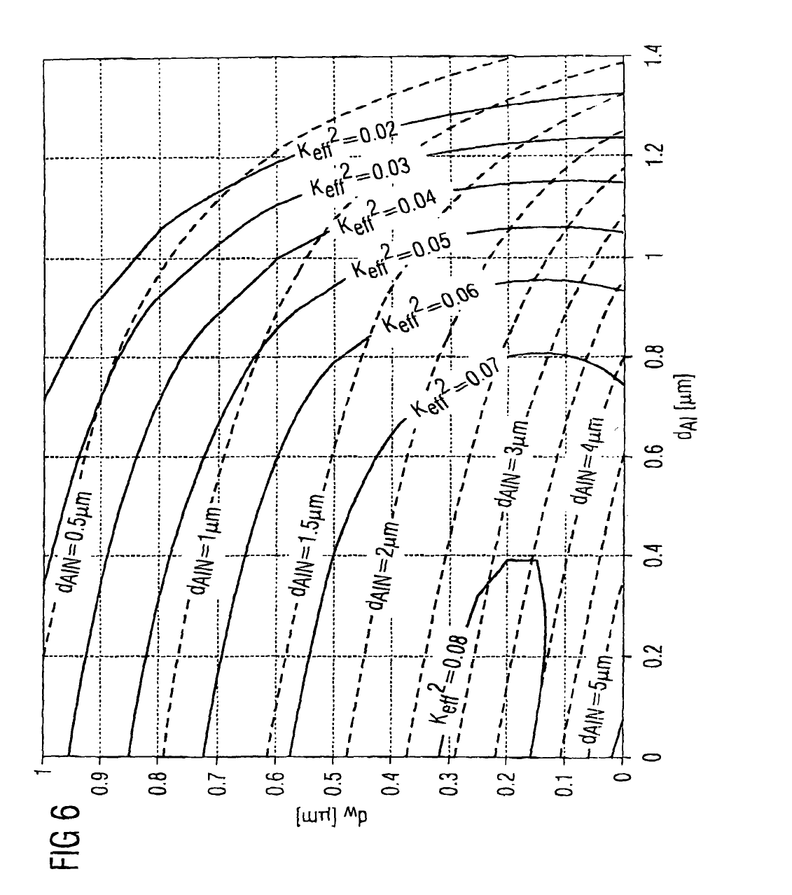

FIG. 6 shows a contour plot of the effective coupling coefficient (solid lines) and also the thickness of the piezoelectric layer of resonators constructed in a way analogous to the third resonator, as a function of the thickness of the electrodes and of the compression layers.

Provided in the first comparative example is a first resonator, which has a piezoelectric layer P′ made of AlN, which is arranged between a first electrode E1′ made of aluminum and a second electrode E2′ made of aluminum. The associated stress field at resonance shows a strong variation over the piezoelectric layer P′ (see FIG. 3). Since the piezoelectric coupling is proportional to the average stress, regions near the electrodes E1′, E2′ contribute less than the regions in the middle of the piezoelectric layer P′.

Provided in the second comparative example is a second resonator, which has a piezoelectric layer P″ made of AlN, which is arranged between a first electrode E1″ made of tungsten and a second electrode E2″ made of tungsten. The stress distribution has a strong gradient in the electrodes E1″, E2″ and is relatively constant over the piezoelectric layer P″ (see FIG. 4). This leads to strong coupling of all the regions of the piezoelectric layer P″. The high acoustic impedance of the tungsten “compresses” as it were the acoustic wave in the piezoelectric layer P″.

Provided in the exemplary embodiment is a third resonator, which has a series of layers for converting acoustic waves and changes in electrical voltage into one another. The series of layers comprises a first electrode E1 made of aluminum, over that a first compression layer V1 made of tungsten, over that a piezoelectric layer P made of AlN, over that a second compression layer V2 made of tungsten and over that a second electrode E2 made of aluminum. The stress distribution at resonance corresponds almost to that of the second resonator (see FIG. 5). The compression effect is consequently still present when the second resonator is provided with further layers (here aluminum). Although the acoustic wave in the aluminum has a small gradient, the tungsten compresses the acoustic stress (and consequently the acoustic energy) in the piezoelectric layer. The tungsten consequently serves as an “acoustic compression layer”.

The resonators of the two comparative examples and of the exemplary embodiment are designed such that they have the same resonant frequency and approximately the optimum effective coupling coefficient possible in each case.

The compression layer achieves the effect that the stress field forming in the piezoelectric layer is comparatively homogeneous, in order to achieve good coupling between the electric field and the stress field. This contributes to a higher coupling coefficient. On the other hand, the compression layer contains regions of lower stress, which, if they were to lie in the piezoelectric layer, would contribute comparatively little to the coupling. The “compression” of the stress field allows the resonator to be formed thinner overall, with the resonant frequency remaining the same.

With the aid of FIG. 6, a resonator with desired boundary conditions can be produced: as an example, a resonator is to have a coupling coefficient of >0.06, and Al electrodes at least 200 nm thick to reduce the series resistances. If the line for the squared coupling coefficient k_{eff}²=0.06 is followed up to that point at which the thickness of the Al electrodes is d_{Al}=0.2 μm, a thickness of the tungsten compression layers of about 700 nm and a thickness of the piezoelectric layer of about 1.2 μm are obtained. Furthermore, it is evident that, with thickening of the Al electrodes to 600 nm and reduction of the tungsten compression layers to 650 nm, both the thickness of the piezoelectric layer and the coupling coefficient remain approximately constant, but the series resistance can be reduced once again considerably. As a comparison: an equivalent resonator with Al electrodes without compression layers would have a thickness of the Al electrodes of about 900 nm and a thickness of the piezoelectric layer of about 3.5 μm. An impedance-matched resonator would consequently be almost three times larger and would need 9 times the amount of aluminum nitride.

Acoustic impedances of some materials are listed below.

| | Acoustic impedance in |
|---|---|
| Material | 10⁶ Kg/m²s |
| Al | 17.3 |
| W | 101 |
| AlN | 34.0 |
| Mo | 63.1 |
| Ir | 98 |
| Pt | 69.7 |
| Ta | 65.3 |
| TiW | 64.2 |
| Cu | 40.6 |
| Au | 62.5 |
| WSi | 90 |
| Cr | 47.4 |
| Al₂O₃ | 44.3 |
| SiN | 36.2 |
| Ta₂O₅ | 38 |
| ZnO | 36 |
| PZT | 17.3 |
| Ag | 17.2 |

List of Designations

List of designations

| | |
|---|---|
| E1, E2, E1′, E2′, E1′′, E2′′ | electrode |
| P, P′, P′′ | piezoelectric layer |
| V1, V2 | compression layer |

1. An acoustic resonator with a first electrode (E1), a second electrode (E2) and a piezoelectric layer (P) arranged in between, characterized in that a first acoustic compression layer (V1), which has a higher acoustic impedance than the first electrode (E1), is arranged between the first electrode (E1) and the piezoelectric layer (P).

2. The acoustic resonator as claimed in claim 1, in which the material of the first compression layer (V1) is chosen such that the ratio of the acoustic impedance of the first compression layer (V1) to the acoustic impedance of the piezoelectric layer (P) is as great as possible.

3. The acoustic resonator as claimed in one of claims 1 to 2, in which the first compression layer (V1) consists substantially of W, Mo, Ir, Pt, Ta, TiW, TiN, Au, WSi, Cr, Al₂O₃, SiN, Ta₂O₅ or zirconium oxide.

4. The acoustic resonator as claimed in one of claims 2 or 3, in which the material of the first electrode (E1) is chosen such that the ratio of the acoustic impedance of the first electrode (E1) to the acoustic impedance of the first compression layer (V1) is as small as possible.

5. The acoustic resonator as claimed in one of claims 1 to 4, in which the first electrode (E1) has a higher electrical conductivity than the first compression layer (V1).

6. The acoustic resonator as claimed in one of claims 1 to 5, in which the first electrode (E1) and/or the second electrode (E2) consist(s) substantially of aluminum, titanium, silver or copper.

7. The acoustic resonator as claimed in one of claims 1 to 6, in which a second acoustic compression layer (V2), which corresponds to the first compression layer (V1) and has a higher acoustic impedance than the second electrode (E2), is arranged between the second electrode (E2) and the piezoelectric layer (P).

8. The acoustic resonator as claimed in one of claims 1 to 6, in which the first compression layer (V1) consists substantially of a conductive material.

9. The acoustic resonator as claimed in claim 7 or 8, in which the second compression layer (V2) consists substantially of a conductive material.
